(19) United States
(12) Patent Application Publication
(10) Pub. No.: US 2006/0022330 A1
(43) Pub. Date: Feb. 2, 2006

(54) Porous silicon heat sinks and heat exchangers and related methods

(76) Inventor: Jonathon Mallari, Bothell, WA (US)

Correspondence Address: THOMAS LOOP, P.O. BOX 21466, SEATTLE, WA, 98111, US

(21) Appl. No.: 11/064,544

(22) Filed: Feb. 23, 2005

Related U.S. Application Data
(60) Provisional application No. 60/547,380, filed on Feb. 23, 2004.

(51) Int. Cl. H01L 23/34; H01L 23/04

(52) U.S. Cl. 257/717; 257/730

(57) ABSTRACT

The invention disclosed herein relates to a heat sink or heat exchanger derived from a planar silicon substrate (e.g., a silicon wafer). In some embodiments, a cooling fluid (gas or liquid) is flowing through the plurality of flow-through pores that extend through the planar silicon substrate. In still further embodiments, the present invention is directed to methods of using a porous silicon substrate as a heat sink or heat exchanger to dissipate and/or transfer heat away from a device such as, for example, a microprocessor associated with a computer system. In this regard, the inventive method comprises at least the following steps: allowing heat to dissipate away from the heated component and into the porous silicon substrate; and passing a first cooling fluid through the plurality of flow-through pores of the porous silicon substrate such that heat is transferred away from the porous silicon substrate and into the first cooling fluid.

### CROSS-REFERENCE TO RELATED APPLICATION

This application claims the benefit of priority to U.S. Provisional Application No. 60/547,380 filed Feb. 23, 2004, which provisional application is incorporated herein by reference in its entirety.

### TECHNICAL FIELD

The present invention relates generally to heat sinks and heat exchangers and, more specifically, to heat sinks and heat exchangers made from silicon substrates as well as to methods relating thereto.

### BACKGROUND OF THE INVENTION

A heat sink is a physical device adapted to facilitate bulk heat dissipation by conduction (i.e., transfer of heat from one substance to another by direct contact) and by convection (i.e., transfer of heat by the motion of or within a fluid), and are often used in association with electronic circuitry such as, for example, electronic circuitry embedded within computer systems. In general, there are two types of heat sinks: active heat sinks and passive heat sinks. Active heat sinks utilize power coupled to a mechanical fan or other Peltier cooling device, whereas passive heat sinks have no mechanical components and generally dissipate heat through convection only (e.g., a finned radiator). Similarly, a heat exchanger is a physical device adapted to transfer heat from one fluid to another without fluid mixing. A typical heat exchanger generally consists essentially of a series of “finned” (increases outer surface area) tubes having a first internal fluid flow of a higher temperature, and a second external fluid flow of a lower temperature that runs over the outer surface of the finned tubes to be cooled.

For small current-consuming electronic devices such as transistors, integrated circuits, and the like, it is generally unnecessary to consider heat dissipation or heat transfer because these type of devices generate very little heat. Other electronic devices such as microprocessors used in computer systems, however, generate lots of heat (which heat tends to increase the temperature of the device). Moreover, data processing speed and efficiency of many microprocessor devices depend, in large part, on how internally generated heat is controlled and removed. Existing heat sinks and heat exchangers do not in all instances effectively control and remove internally generated heat, especially in the context of micro-scale devices such as microprocessors.

Accordingly, there is still a need in the art for new and improved heat sinks and heat exchangers and, more specifically, there is a need for heat sinks and heat exchangers configured to dissipate heat away from micro-scale devices. The present invention fulfills these needs and provides for further related advantages.

### BRIEF DESCRIPTION OF THE DRAWINGS

The drawings are intended to be illustrative and symbolic representations of certain exemplary embodiments of the present invention and as such they are not necessarily drawn to scale.

FIG. 1 is a pictorial side elevational view of a heat sink in accordance with one embodiment of the present invention.

FIG. 2 is a side view of a porous silicon substrate useful as a heat sink or heat exchanger in accordance with an embodiment of the present invention (but where the backside of the substrate has not yet been ground or etched so as to “open” the plurality of flow-through pores).

FIG. 3 is a partial side elevational view of a porous silicon substrate useful as a heat sink or heat exchanger in accordance with an embodiment of the present invention (and wherein the plurality of flow-through pores define an ordered array of pores).

FIG. 4 is a top view of a porous silicon substrate useful as a heat sink or heat exchanger in accordance with an embodiment of the present invention.

FIG. 5 is another top view of a porous silicon substrate useful as a heat sink or heat exchanger in accordance with an embodiment of the present invention.

FIG. 6 is yet another top view of a porous silicon substrate useful as a heat sink or heat exchanger in accordance with an embodiment of the present invention.

### SUMMARY OF THE INVENTION

In brief, the present invention relates generally heat sinks and heat exchangers and, more specifically, to heat sinks and heat exchangers made from silicon substrates, preferably silicon wafers, as well as to methods relating thereto. In some embodiments, the present invention is directed to and comprises a heat sink or heat exchanger derived from a planar silicon substrate (e.g., a silicon wafer), wherein the planar silicon substrate has a top surface (exposed to a top region) and a bottom surface (exposed to a bottom region), and wherein the planar silicon substrate has a plurality flow-through pores that extend through the planar silicon substrate thereby fluidicly connecting the top region to the bottom region.

In other embodiments, the present invention is directed to a heat sink or heat exchanger derived from a planar silicon substrate as above and further comprising a cooling fluid (gas or liquid) flowing through the plurality of flow-through pores that extend through the planar silicon substrate. In still further embodiments, the present invention is directed to methods of using a porous silicon substrate as a heat sink or heat exchanger to dissipate and/or transfer heat away from a device such as, for example, a microprocessor associated with a computer system. In this regard, the invention in one embodiment is directed to a method for dissipating heat away from a heated component thermally coupled to a porous silicon substrate, wherein the method comprising at least the following steps: allowing heat to dissipate away from the heated component and into the porous silicon substrate; and passing a first cooling fluid through the plurality of flow-through pores of the porous silicon substrate such that heat is transferred away from the porous silicon substrate and into the first cooling fluid.

These and other aspects of the present invention will become more evident upon reference to the following detailed description and attached drawings. It is to be understood, however, that various changes, alterations, and substitutions may be made to the specific embodiments disclosed herein without departing from their essential spirit and scope. In addition, it is to be further understood that the drawings are intended to be illustrative and symbolic representations of certain exemplary embodiments of the present invention and as such they are not necessarily drawn to scale. Finally, it is expressly provided that all of the various references cited herein are incorporated herein by reference in their entireties for all purposes.

### DETAILED DESCRIPTION OF THE INVENTION

As noted above, the present invention relates generally heat sinks and heat exchangers and, more specifically, to heat sinks and heat exchangers made or derived from silicon substrates such as, for example, silicon wafers. As is appreciated by those skilled in the art, a heat sink is a physical device adapted to facilitate bulk heat dissipation by conduction and by convection, and similarly a heat exchanger is a physical device adapted to transfer heat from one fluid to another without fluid mixing. The silicon substrates of the present invention are, when appropriately thermally coupled to a heat source, particularly useful for heat dissipation and transfer because silicon has a relatively high thermal conductivity (˜148WK⁻¹m⁻¹). Moreover, silicon may be made porous so as to have a very high surface area to bulk volume ratio and a cooling fluid may be made to flow through porous silicon so as to better effectuate heat removal. Thus, it has been found that porous silicon, when thermally coupled to a micro-scale heated component, may be used to effectively dissipate away from the heated component.

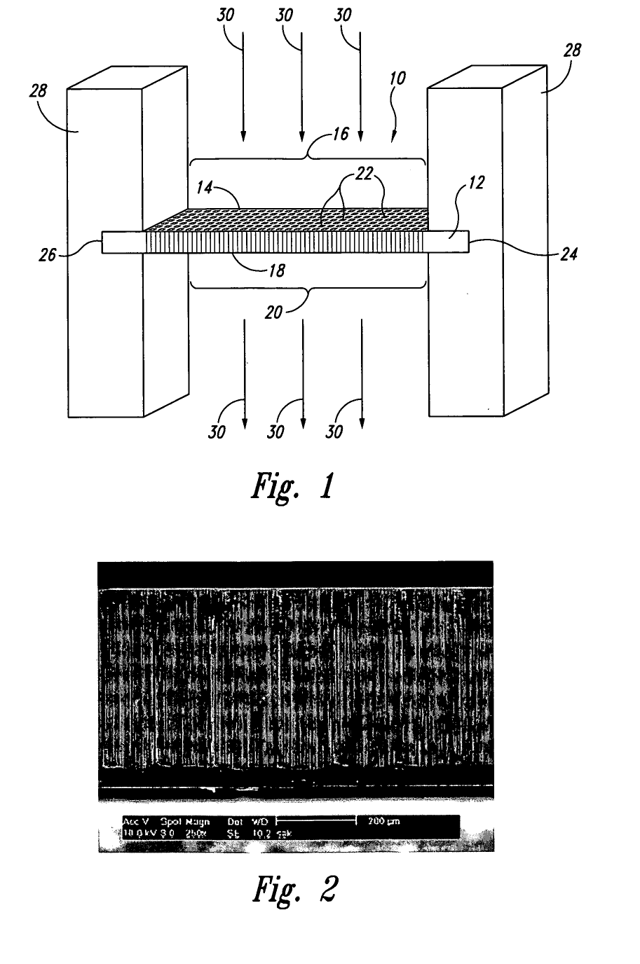

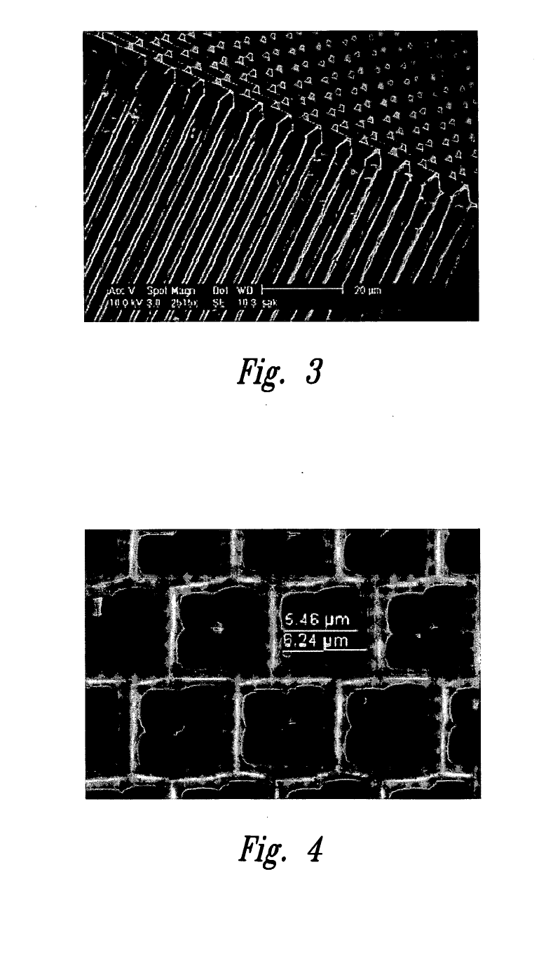

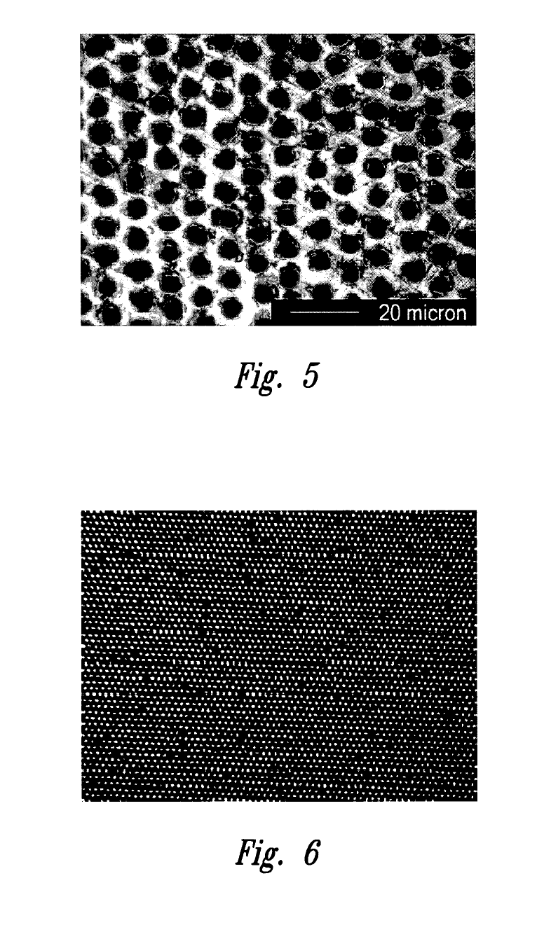

Referring now to FIG. 1, the present invention in one embodiment comprises a heat sink 10 derived from a planar silicon substrate 12 (e.g., a silicon wafer), wherein the planar silicon substrate 12 has a top surface 14 that is exposed to a top region 16 and a bottom surface 18 that is exposed to a bottom region 20. As shown, the silicon substrate 12 has a plurality flow-through pores 22 that extend through the silicon substrate 12 thereby fluidicly connecting the top region 16 to the bottom region 20. The silicon substrate 12 has first and second ends 24, 26 that are coupled to one or more heat sources 28 (heated components of higher temperature). In this configuration, heat energy is able to dissipate away from the one or more heat sources 28 and into the silicon substrate 12 (of a lower temperature); a cooling fluid 30 (depicted by arrows and of a still lower temperature) may then be made to flow from the top region 16 and through the plurality of flow-through pores 22 and into and through the bottom region 20 of the silicon substrate 12. In so doing, heat energy is able to transfer from the silicon substrate and into the flowing cooling fluid 30 thereby effectuating heat removal from the silicon substrate 12 (and, in turn, the one or more heat sources 28). As is appreciated by those skilled in the art, the cooling fluid 30 may be a liquid such as, for example, a synthetic hydrocarbon polyalphaolefin (PAO)-based coolant fluid (available from Royal Lubricants Company, Inc. NJ and Castrol, Inc. CA, U.S.A.) or a more conventional fluid such a water glycol mixture or a fluorinated oil. The cooling fluid 30 may also be part of a recirculating closed cooling loop (not shown). In still other embodiments, the cooling fluid 30 may be a gas such, for example, air.

In view of the foregoing, the inventive heat sinks and heat exchangers disclosed herein are based on porous silicon substrates that have a plurality of flow-through pores adapted to flow a fluid coolant stream from one side of the substrate to the other. In this configuration, the internal surface area of the pores are generally readily accessible to one or more flowing gaseous and/or liquid coolant streams. The flow-through pores (optionally interconnecting with one another) of the planar silicon substrate define a porous silicon structure, wherein the porous silicon may be microporous silicon (i.e., average pore size <2 nm), mesoporous silicon (i.e., average pore size of 2 nm to 50 nm), macroporous silicon (i.e., average pore size >50 nm), or a combination thereof. In one preferred embodiment, the pores have diameters of about 2 to 20 microns and regularly spaced apart (center to center) from one another a distance of about 5 to about 20 microns. The thickness of the silicon substrate generally ranges from about 50 to about 500 microns; preferably, however, from about 200 to about 400 microns. The increased surface area of the pores help to dissipate heat away from one or more heated components thermally coupled to the porous silicon heat sink, especially when a cooling fluid is passed through the pores.

Moreover, and in the context of some embodiments of the present invention, it has been discovered that porous silicon-based substrates are particularly useful as heat sinks and heat exchangers, in part because such substrates are able to provide a high surface area to bulk volume ratio, have good mechanical strength, and because silicon has a high thermal conductivity (˜148WK⁻¹m⁻¹). Because of these physical characteristic, among others, and because silicon-based substrates are amenable to micro-fabrication techniques, the heat sinks and heat exchangers of the present invention may be manufactured within a small form factor (micro-scale) and are thus suitable for integration with small heat generating electronic devices such as, for example, personal and laptop computers.

Accordingly, and without limitation to any particular methodology, the silicon-based heat sinks and heat exchangers disclosed herein may be manufactured by using standard microelectromechanical systems (“MEMS”) technologies such as, for example, wet chemical etching, deep reactive ion etching (“DRIE”), hydrofluoric acid (HF) anodic etching, alkaline etching, plasma etching, and lithography. By using these techniques, a porous silicon heat sink or heat exchanger may be produced, wherein each porous region (of the substrate) may have any number of pores and pores sizes such as, for example, random or ordered pore arrays—including pore arrays having selected pore diameters, depths, and distances relative to one another. In short, the present invention is inclusive of all silicon substrate support structures, including combinations thereof, that have any number of possible porosities and/or void spaces associated therewith.

Porous silicon substrates useful as heat sinks and heat exchangers may be formed by silicon micro-machining and/or wet chemical techniques (employed by the semiconductor industry) such as, for example, anodic polarization of silicon in hydrofluoric acid. As is appreciated by those skilled in the art, the anodic polarization of silicon in hydrofluoric acid (HF) is a chemical dissolution technique and is generally referred to as HF anodic etching; this technique has been used in the semiconductor industry for wafer thinning, polishing, and the manufacture of thick porous silicon films. (See, e.g., Eijkel, et al., “A New Technology for Micromachining of Silicon: Dopant Selective HF Anodic Etching for the Realization of Low-Doped Monocrystalline Silicon Structures,” IEEE Electron Device Ltrs., 11(12):588-589 (1990)). In the context of the present invention, it is to be understood that the porous silicon regions of the silicon substrate may each be microporous silicon (i.e., average pore size <2 nm), mesoporous silicon (i.e., average pore size of 2 nm to 50 nm), or macroporous silicon (i.e., average pore size >50 nm).

More specifically, porous silicon substrates useful in the context of the present invention may be formed by a photoelectrochemical HF anodic etching technique applied to each side of a silicon wafer, wherein selected oxidation-dissolution of silicon occurs under a controlled current density. (See, e.g., Levy-Clement et al., “Porous n-silicon Produced by Photoelectrochemical Etching,” Applied Surface Science, 65/66: 408-414 (1993); M. J. Eddowes, “Photoelectrochemical Etching of Three-Dimensional Structures in Silicon,” J. of Electrochem. Soc., 137(11):3514-3516 (1990); and V. Lehman, Electrochemistry of Silicon, Wiley-VCH Verlag GmbH, Weinheim, Germany (2002).) An advantage of this relatively more sophisticated technique over others is that it is largely independent of the different principal crystallographic planes associated with single-crystal silicon wafers (whereas most anisotropic wet chemical etching methods have very significant differences in rates of etching along the different principal crystallographic planes).

For purposes of illustration and not limitation, the following example more specifically discloses actual experimental results associated with capillary flow within a 3×8 cm dual porosity silicon membrane.

### EXAMPLE

### Manufacturing Steps used to Make a Porous Silicon Substrate Useful as a Heat Sink or Heat Exchanger

A porous silicon substrate useful as a heat sink or heat exchanger in accordance with an embodiment of the present invention were made in the following exemplary manner.

Wafer Spec: Si Wafers were provided by Wacker-Siltronic (Munich, Germany) wherein each wafer had an approximate 3000-3500 Å layer of Low Temperature Oxide (LTO) on the front side and with approximate specifications as set forth in the Table below.

TABLE 1
SILICON WAFER SPECIFICATIONS

| | | Crystal | Dopant | | ρ | | | Dif | | Primary |
|---|---|---|---|---|---|---|---|---|---|---|
| Diameter | Thickness | Orient | Type | Type | [Ω- | TTV | Growth | Length | Grade | Fat |
| [mm] | [μm] | [−] | [−] | [−] | cm] | [_{μ}m] | [−] | [_{μ}m] | [−] | [_{μ}m] |
| 100 | 550 | 100 | P | n | 20-30 | <5 | CZ | >400 | Hi-Ref | 30-35 |

Wafer Cleaning: A single wafer was cleaned with Nanostrip for 30 minutes, then in BOE for 15 minutes, and then with a spin rinse dryer (SRD).

Al Contact Doping: The wafer was doped by using a spin on dopant on the backside and inserting into a furnace. The furnace was heated to an approximate temperature of 950° C. under an atmosphere of nitrogen (6 standard liters per min or STLM) and Oxygen (0.2 STLM) with a temperature ramp up cycle of about 10° C./min. The wafer was then heated at 925° C. for 30 minutes (in order to achieve a dopant depth of about 0.24 μm and having a measured sheet resistance with a 4 point probe of about 14-18 Ω-squares). The furnace was then cooled to about 850° C. with a ramp down cycle of about 5° C./min and the oxygen was increased 2 SLM. The wafer was then removed and allowed to cool. The wafer was then cleaned in BOE for about 10 minutes. The wafer was then cleaned in a SRD.

Photolithography: The front side of the wafer was then patterned with photoresist (namely, and ordered array of 5 μm squares with an 8 μm pitch). The photoresist was spun onto the wafer by using a spinner at 3000 rpm. The wafer was then baked for about 30 minutes at about 90° C. The photoresist was then exposed to UV light for about 3 seconds through a chrome-on-glass mask. The unexposed photoresist was then removed with a developer. The wafer was then cleaned in a SRD.

RIE: The patterned LTO was etched using an RIE (reactive ion etcher) exposing the bare silicon underneath.

Barrel Etch: The wafer was cleaned in a Barrel Etch to remove residue from the RIE process.

Photoresist Strip: The exposed photoresist was then removed using EKC830 for about 10 minutes and then AZ300T for about 5 minutes. The wafer was cleaned in a SRD.

Metallization: An approximate 5000 Å aluminum film was then deposited on the backside of the wafer using PVD.

Photolithography: The backside was patterned with photoresist. The photoresist was spun onto the wafer by using a spinner at 3000 rpm. The wafer was then baked for about 30 minutes at about 90° C. The photoresist was then exposed to UV light for 3 about seconds through a mask. The unexposed photoresist was then removed with a developer. The wafer was then cleaned in a SRD.

Al Etch: The unexposed aluminum was etched with Alameda Al etchant for about 20 seconds at about 100° C. to expose the doped bare silicon.

Photoresist Strip: The exposed photoresist was removed using EKC830 for about 10 minutes and then AZ300T for about 5 minutes. The wafer was then cleaned in a SRD.

Metal Anneal: The aluminum was annealed by placing in furnace and heated to about 400° C. with a ramp up of about 110° C./min under 6 STLM of Argon. The wafer was then heated at about 400° C. for about 30 minutes. The furnace was then cooled to room temperature with a ramp down of about 5° C./min under 6 STLM of Nitrogen.

KOH: The wafer was placed in a fixture which exposed the front side only. The front side was then etched in about 28% KOH at 65° C. for about 15 minutes. The wafer was then cleaned in a SRD.

Anodic Si Etching: The wafer was anodically etched in 4-6 wt % HF for 16-24 hours under a bias of 1.4 to 6V and a current density of 18-25 mA/cm² at 14-20° C.

Wafer Cleaning: The wafer was cleaned in a SRD.

Grinding: The backside of the wafer was anodically etched in 5 wt % HF for 11-12 hours under a bias of 0.8-1.5V (monotonic increase) and a current density of 5.5-4.1 mA/cm² at 20-16° C. (monotonic decrease).

Wafer Cleaning: The wafer was then cleaned in a bath for 8-12 hours, wherein the bath consisted essentially of about 4L of 5 wt % HF/10 mL of 60 wt % HNO₃/10 mL of 20 wt % Acetic Acid (400:1:1). The wafer was then cleaned in a SRD. The wafer was then sonicated in isopropanol for 30 minutes.

Barrel Etch: The wafer was cleaned in a Barrel Etch to remove residue from the earlier processes.

While the present invention has been described in the context of the embodiments illustrated and described herein, the invention may be embodied in other specific ways or in other specific forms without departing from its spirit or essential characteristics. Therefore, the described embodiments are to be considered in all respects as illustrative and not restrictive. The scope of the invention is, therefore, indicated by the appended claims rather than by the foregoing description, and all changes that come within the meaning and range of equivalency of the claims are to be embraced within their scope.

What is claimed is:

1. A method for dissipating heat away from a heated component thermally coupled to a porous silicon substrate, wherein the silicon substrate has a front surface, a back surface, and a plurality of flow-through pores extending through the silicon substrate and connecting the front surface to the back surface, the method comprising at least the following steps:
allowing heat to dissipate away from the heated component and into the porous silicon substrate; and
passing a first cooling fluid through the plurality of flow-through pores of the porous silicon substrate such that heat is transferred away from the porous silicon substrate and into the first cooling fluid.

2. The method of claim 1 wherein the flow-through pores are microporous, mesoporous silicon, macroporous silicon, or a combination thereof.

3. The method of claim 1 wherein the porous silicon substrate is derived from a silicon wafer.

4. The method of claim 1 wherein the porous silicon substrate has a thickness ranging from 50 to about 500 microns.

5. The method of claim 1 wherein the heated component is integrally connected to the porous silicon substrate.

6. The method of claim 1 wherein the first cooling fluid is air.
